(19) United States
(12) Patent Application Publication
(10) Pub. No.: US 2017/0086328 A1
(43) Pub. Date: Mar. 23, 2017

(54) SUPPORT STAND APPARATUS AND METHOD TO ENHANCE COOLING AND HEAT DISSIPATION OF ELECTRONIC DEVICES

(71) Applicants: Hoang Nguyen Ly, SAN JOSE, CA (US); MASSOUD AREFI ANBARANI, MILPITAS, CA (US); BE VAN VO, SANTA CLARA, CA (US); THIEN NGUYEN VO, SANTA CLARA, CA (US)

(72) Inventors: Hoang Nguyen Ly, SAN JOSE, CA (US); MASSOUD AREFI ANBARANI, MILPITAS, CA (US); BE VAN VO, SANTA CLARA, CA (US); THIEN NGUYEN VO, SANTA CLARA, CA (US)

(21) Appl. No.: 15/272,251

(22) Filed: Sep. 21, 2016

Related U.S. Application Data
(60) Provisional application No. 62/221,630, filed on Sep. 22, 2015.

(51) Int. Cl. H05K 7/20; H05K 5/02; F16B 47/00; F16B 1/00; F16M 11/22; A47B 23/04

(52) U.S. Cl. CPC H05K 7/20; F16M 11/22; A47B 23/04; F16B 47/003; F16B 1/00; H05K 5/0204; H05K 5/0234; A47B 2023/049; F16B 2001/0035

(57) ABSTRACT

A support stand apparatus and method to elevate an electronic device above a flat surface to enhance heat dissipation and cooling is provided. The support stand apparatus includes a base member with a top face having a concave surface and a bottom face having a slot, a magnet disposed within the slot and coupled to the base member, a metallic member detachably coupled to a bottom portion of the electronic device and having a convex surface. The base member is oriented to permit the concave surface of the top face to receive the convex surface of the metallic member to support the electronic device in an elevated position above the flat surface.

### RELATED APPLICATION

The application claims priority to provisional patent application U.S. Ser. No. 62/221,630 filed on Sep. 22, 2015, the entire contents of which is herein incorporated by reference.

### BACKGROUND

The embodiments herein relate generally to devices and methods for electronic devices to promote cooling and heat dissipation.

Individuals typically own a variety of electronic devices including laptops, game consoles, tablets, DVD players, and the like. These devices generate significant heat when in use, which can cause the devices to overheat, thereby negatively affecting the functionality and durability of the devices. Although these devices commonly use one or more fans to dissipate generated heat, there remains overheating concerns of the devices, especially when they are placed on a flat surface such as the ground, table, shelf, or the like. In this position, there is not adequate space beneath the device to effectively circulate ambient air to cool the device.

Several accessories for cooling electronic devices require the use of additional fans. However, each accessory requires a power source to operate, which significantly reduces the device's battery life if connected to the electronic device. Several devices exist to elevate electronic devices above a table as disclosed in U.S. Patent Application Publication 2011/0069447, 2012/0305733 and 2012/0252543. However, these devices are undesirable because they require the use of multiple components and/or complex parts, which are prone to premature wear and ultimately a reduced operational lifetime.

As such, there is a need in the industry for a support stand apparatus and method that overcomes the limitations of the prior art, which effectively enhances cooling and heat dissipation of an electronic device. There is a further need for a support stand apparatus that comprises simple components that are easy to assemble and disassemble from the electronic device.

### SUMMARY

A support stand apparatus configured to elevate an electronic device above a flat surface to enhance heat dissipation and cooling is provided. The support stand apparatus comprises a base member comprising a top face, a bottom face and side faces connecting the top and bottom faces, the top face comprising a concave surface and the bottom face comprising a slot, a magnet disposed within the slot and coupled to the base member, a metallic member detachably coupled to a bottom portion of the electronic device and comprising a convex surface, wherein the base member is oriented to permit the concave surface of the top face to receive the convex surface of the metallic member to support the electronic device in an elevated position above the flat surface, wherein forces generated by the magnet attract the metallic member, thereby securing the metallic member to the concave surface of the base member.

In certain embodiments of the invention, a method for elevating an electronic device above a flat surface to enhance heat dissipation and cooling is provided. The method comprises providing the support stand apparatus, affixing an adhesive layer of the metallic member of the support stand apparatus to a bottom portion of the electronic device, and maneuvering the base member of the support stand apparatus to permit the concave surface to receive the convex surface of the metallic member. In certain embodiments of the invention, one or more additional support stand apparatuses are provided and coupled to the bottom of the electronic device.

### BRIEF DESCRIPTION OF THE FIGURES

The detailed description of some embodiments of the invention will be made below with reference to the accompanying figures, wherein the figures disclose one or more embodiments of the present invention.

FIG. 1 depicts a perspective view of certain embodiments of the electronic device support stand apparatus shown in use;

FIG. 2 depicts a perspective view of certain embodiments of the electronic device support stand apparatus;

FIG. 3 depicts a perspective view of certain embodiments of the electronic device support stand apparatus;

FIG. 4 depicts an exploded view of certain embodiments of the electronic device support stand apparatus;

FIG. 5 depicts a section view of certain embodiments of the electronic device support stand apparatus taken along line 5-5 in FIG. 1;

FIG. 6 depicts a section view of certain embodiments of the electronic device support stand apparatus shown in use;

FIG. 7 depicts a perspective view of certain embodiments of the electronic device support stand apparatus shown in use in an alternative configuration; and

FIG. 8 depicts a perspective view of certain embodiments of the electronic device support stand apparatus shown in use in an alternative configuration.

### DETAILED DESCRIPTION OF CERTAIN EMBODIMENTS

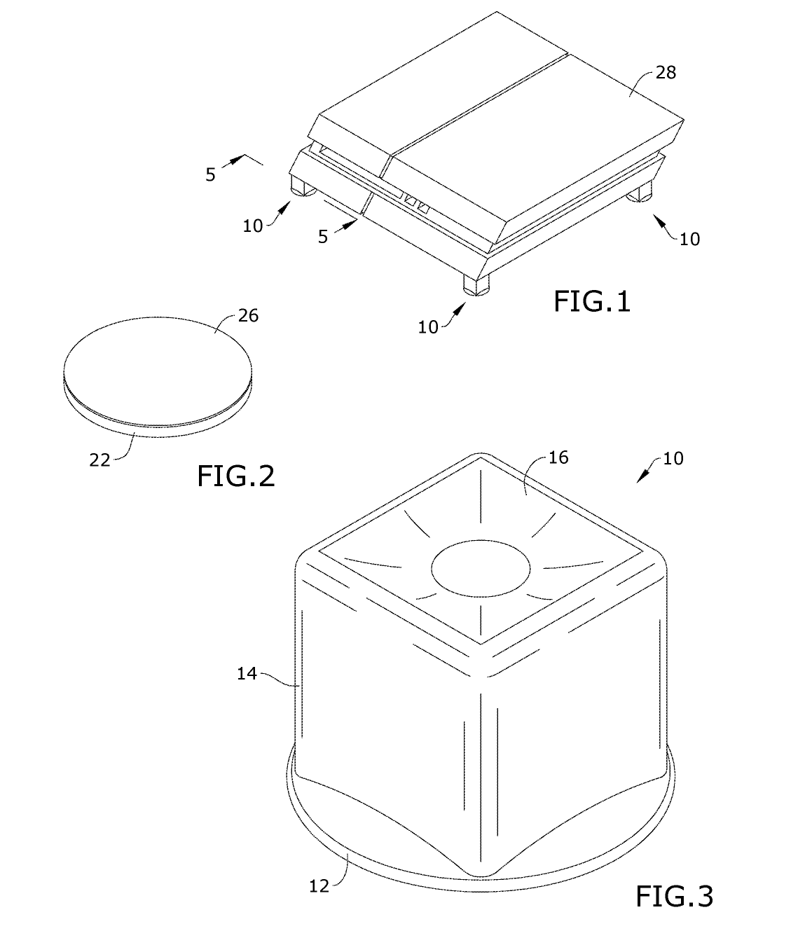

As depicted in FIGS. 1-3 and 7-8, support stand apparatus 10 is configured for use in elevating an electronic device above any flat surface (not shown) including, but not limited to, a table, shelf, floor, and the like, to enhance ambient airflow around the device. This enhances heat dissipation and cooling, and prevents the electronic device from overheating. Exemplary electronic devices include first electronic device 28 such as a video game console, second electronic device 32 such as a laptop, and third electronic device 34 such as a tablet. However, it shall be appreciated that support stand apparatus 10 may be used with alternative types of electronic devices.

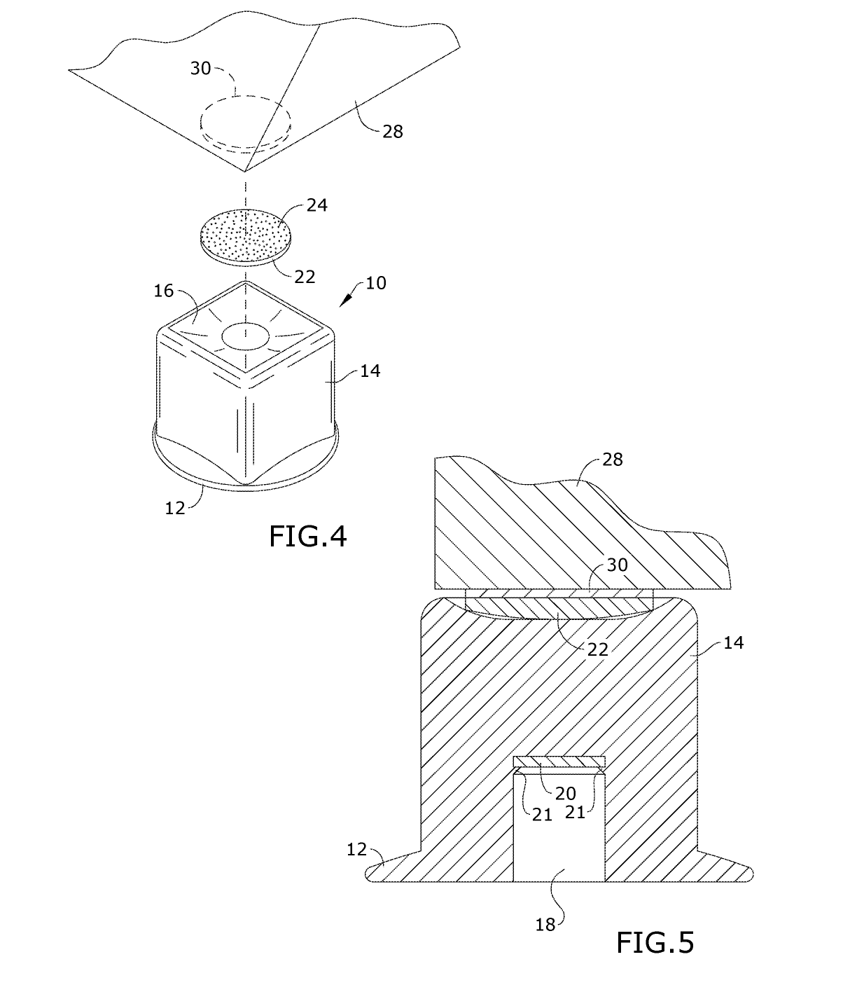

As depicted in FIGS. 2-5, support stand apparatus 10 generally comprises base member 14 and metallic member 22. Base member 14 comprises a top face comprising concave surface 16, a bottom face comprising circular member 12, and side faces connecting the top and bottom faces. Circular member 12 extends outward from the side faces and is configured to be disposed on any flat surface such as a table, shelf, floor, or the like, to enhance stability of support stand apparatus 10 when in use. In one embodiment, each side face of base member 14 comprises a curved edge coupled to circular member 12.

Base member 14 comprises slot 18 extending from the bottom of circular member 12 to a central portion of the base member. The interior wall of slot 18 comprises retainer ledge 21, which serves as a surface to support magnet 20 within slot 18. In one embodiment, retainer ledge 21 extends approximately 1 mm outward from the interior wall of slot 18. Once secured in place within slot 18 and in contact with retainer ledge 21, magnet 20 is retained in a stationary position. Magnet 20 is preferably made from neodymium or other rare earth magnetic materials.

Base member 14 is preferably made from injection molded plastic such as POM, ABS, or the like, and comprises an approximate height of ¾″ and width of ¾″ with the exception of circular member 12. In a preferred embodiment, circular member 12 comprises an approximate diameter of 1″. However, the dimensions of base member 14 may vary. In alternative embodiments, base member 14 may be made from aluminum, magnesium or other metals known in the field.

As depicted in FIGS. 2 and 4-5, metallic member 22 comprises a bottom convex surface and upper adhesive layer 24. Adhesive backing 26 covers adhesive layer 24 of metallic member 22 until it is ready for use. It shall be appreciated that metallic member 22 may be made from iron, nickel, cobalt or other alloys and metals known in the field. The convex surface of metallic member 22 is configured to conform to contours of concave surface 16 of base member 14. Adhesive layer 24 of metallic member 22 is configured to be secured to foot member 30 of first electronic device 28 or any other bottom portion of the device.

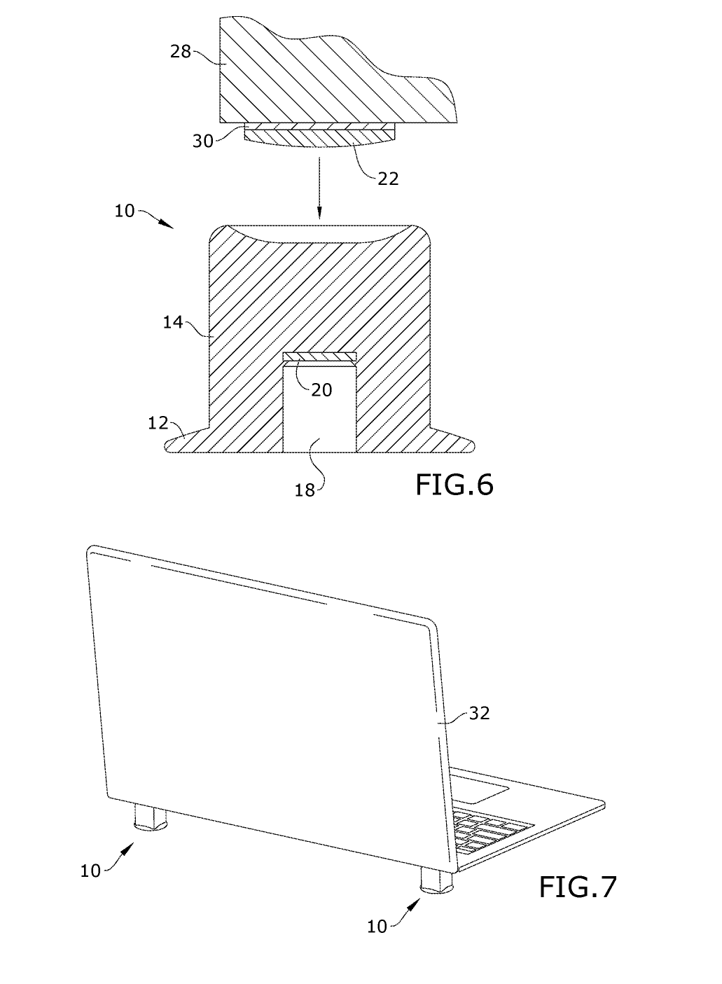

In operation, support stand apparatus 10 is coupled to first electronic device 28. Specifically, adhesive backing 26 of metallic member 22 is removed to permit adhesive layer 24 to be pressed against foot member 30 or another bottom portion of first electronic device 28. Base member 14 is oriented to permit concave surface 16 to receive the convex surface of metallic member 22 as depicted in FIGS. 5-6. Magnet 20 generates forces that attract metallic member 22. This helps to secure metallic member 22 to concave surface 16 of base member 14.

Additional support stand apparatuses 10 may be secured to first electronic device 28 in the same manner. As depicted in FIG. 1, four support stand apparatuses 10 are secured to the corners of first electronic device 28. In this configuration, support stand apparatuses 10 support first electronic device 28 in an elevated position above any flat surface (not shown) such as a table, shelf, floor, and the like. In this position, there is sufficient space around and beneath first electronic device 28 to enhance cooling and heat dissipation of the device when in use.

It shall be appreciated that support stand apparatuses 10 may be removed from the electronic device when no longer needed. Each pair of support stand apparatuses 10 can be stacked together such that concave surfaces 16 of the apparatuses contact each other. Attractive forces generated by magnets 20 of the pair of support stand apparatuses secure the apparatuses together for an easy storage.

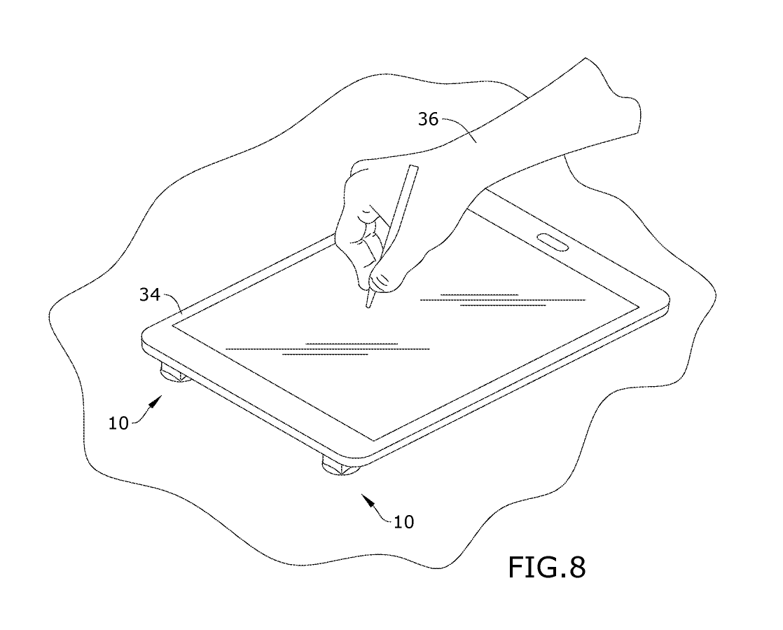

FIGS. 7-8 depict support stand apparatuses 10 in use with alternative electronic devices. As depicted in FIG. 7, a pair of support stand apparatuses 10 are coupled to the bottom of second electronic device 32, which is a laptop. In tests conducted, it has been determined that the use of support stand apparatuses 10 in this configuration has reduced the temperature at the bottom of the laptop by a mean of 3 degrees Celsius and a maximum of 5 degrees Celsius. In addition, this configuration of support stand apparatuses 10 at the rear of second electronic device 32 is advantageous because it improves the angle of the keyboard to a more comfortable and ergonomic position for the user.

As depicted in FIG. 8, a pair of support stand apparatuses 10 are coupled to the bottom of third electronic device 34, which is a tablet. This configuration enhances heat dissipation and cooling of the device, and provides user 36 with a more comfortable and ergonomic hand position when interacting with the device.

It shall be appreciated that the components of support stand apparatus 10 described in several embodiments herein may comprise any alternative known materials in the field and be of any color, size and/or dimensions. It shall be appreciated that the components of support stand apparatus 10 described herein may be manufactured and assembled using any known techniques in the field.

Persons of ordinary skill in the art may appreciate that numerous design configurations may be possible to enjoy the functional benefits of the inventive systems. Thus, given the wide variety of configurations and arrangements of embodiments of the present invention the scope of the invention is reflected by the breadth of the claims below rather than narrowed by the embodiments described above.

What is claimed is:

1. A support stand apparatus configured to elevate an electronic device above a flat surface to enhance heat dissipation and cooling, the support stand apparatus comprising:
a base member comprising a top face, a bottom face and side faces connecting the top and bottom faces, the top face comprising a concave surface and the bottom face comprising a slot;
a magnet disposed within the slot and coupled to the base member;
a metallic member detachably coupled to a bottom portion of the electronic device and comprising a convex surface;
wherein the base member is oriented to permit the concave surface of the top face to receive the convex surface of the metallic member to support the electronic device in an elevated position above the flat surface, wherein forces generated by the magnet attract the metallic member, thereby securing the metallic member to the concave surface of the base member.

2. The support stand apparatus of claim 1, wherein the bottom face comprises a generally circular member that extends outward from the side faces of the base member, wherein the circular member contacts the flat surface to enhance stability of the base member.

3. The support stand apparatus of claim 2, wherein each side face of the base member comprises a curved edge coupled to the generally circular member of the bottom face.

4. The support stand apparatus of claim 3, wherein the metallic member comprises an adhesive layer configured to contact the bottom portion of the electronic device.

5. The support stand apparatus of claim 4, wherein the adhesive layer of the metallic member is configured to contact a foot member of the electronic device.

6. The support stand apparatus of claim 5, further comprising a retainer ledge coupled to an interior wall of the slot in the base member, wherein the retainer ledge contacts the magnet to secure the magnet within the slot.

7. A method for elevating an electronic device above a flat surface to enhance heat dissipation and cooling, the method comprising:
providing a support stand apparatus, the support stand apparatus comprising:
a base member comprising a top face, a bottom face and side faces connecting the top and bottom faces, the top face comprising a concave surface and the bottom face comprising a slot;
a magnet disposed within the slot and coupled to the base member; and
a metallic member comprising an adhesive layer and a convex surface configured to contact the concave surface of the base member;
affixing the adhesive layer of the metallic member to a bottom portion of the electronic device; and
maneuvering the base member to permit the concave surface to receive the convex surface of the metallic member, thereby permitting the base member to support the electronic device in an elevated position above the flat surface.

8. The method of claim 7, further comprising providing a second support stand apparatus, the second support stand apparatus comprising a base member comprising a top face, a bottom face and side faces connecting the top and bottom faces, the top face comprising a concave surface and the bottom face comprising a slot, a magnet disposed within the slot and coupled to the base member, and a metallic member comprising an adhesive layer and a convex surface configured to contact the concave surface of the base member, affixing the adhesive layer of the metallic member of the second support stand apparatus to another bottom portion of the electronic device, and maneuvering the base member of the second support stand apparatus to permit the concave surface to receive the convex surface of the metallic member of the second support stand apparatus.
